(19) United States
(12) Patent Application Publication
(10) Pub. No.: US 2005/0268855 A1
(43) Pub. Date: Dec. 8, 2005

(54) Evaporative deposition with enhanced film uniformity and stoichiometry

(76) Inventor: Joseph F. Brooks, Nampa, ID (US)

Correspondence Address: DICKSTEIN SHAPIRO MORIN & OSHINSKY LLP, 2101 L Street, NW, Washington, DC, 20037, US

(21) Appl. No.: 11/202,139

(22) Filed: Aug. 12, 2005

Related U.S. Application Data
(62) Division of application No. 10/128,349, filed on Apr. 24, 2002.

(51) Int. Cl. C23C 16/00; B05D 3/00; C23C 8/00

(52) U.S. Cl. 118/726; 427/561; 427/585

(57) ABSTRACT

A method and apparatus for forming a thermally-evaporated binary (or greater) thin film are disclosed in which the surface area of an evaporation container is effectively increased by using an inert medium added to source materials that are to form the binary (or greater) film. Using this method and apparatus, films having better uniformity and stoichiometry are achievable.

### FIELD OF THE INVENTION

This invention relates to the field of deposition of thin films composed of multiple materials by thermal evaporation.

### BACKGROUND

Evaporative deposition techniques are extremely important in the semiconductor industry where there is a necessity for highly uniform and very thin films of various materials. In the semiconductor industry, evaporative deposition is useful in forming a material layer of a desired stoichiometry from a plurality of different materials.

In thermal evaporation techniques, vapor particles can be generated in high vacuum by sublimation or vaporization of a material via a variety of heating sources and then condensed on a substrate. Heating sources include resistive heating sources, lasers, and electron beam sources. Typically, a material source is placed in an evaporation crucible or boat and a heat source, such as resistive heating coils, applies thermal energy to the crucible or boat (indirect resistive heating) causing the material source to melt and vaporize. Upon contacting a cooler surface the vaporized material condenses and forms a film.

Formation of a homogenous thin film having high uniformity and desired stoichiometry by thermal evaporation of a single material is a simple procedure because a homogenous material source will have only a single boiling point, a single freezing point, and there is no opportunity for dissociation. Therefore, under appropriate conditions, a very thin film that is useful for various purposes can be easily formed. However, when a binary (or tertiary or greater) film is desired, problems are presented because of the differing physical characteristics (e.g., melting and boiling points) of the multiple source materials and the ever-present problem of dissociation. Often, when forming binary films by thermal evaporation for semiconductor industrial purposes, a material gradient is unintentionally formed in the thin film where the initial material deposited does not have the desired stoichiometry. This requires longer formation times to reach the desired or required stoichiometric levels and can lead to films that are not as uniform as desired. Such problems increase and are exaggerated as the physical characteristics of the different source materials become increasingly divergent.

### SUMMARY

This invention provides a method for improving the stoichiometric character of a thermal-vapor-deposited material layer formed of materials having different physical (e.g., melting and boiling points) and chemical properties. An inert medium is added to the source materials within an evaporation container (e.g., a crucible) that are to form a binary (or greater) film upon vaporization and condensation. By this method, films of increased uniformity and maintained stoichiometry are achievable.

These and other advantages and features of the invention will be more clearly understood from the following detailed description which is provided in conjunction with the accompanying drawings.

### BRIEF DESCRIPTION OF THE DRAWINGS

FIG. 1 is a cut-away illustration showing source material use in prior art techniques;

FIG. 2 is a cut-away illustration of materials used for evaporative deposition of a thin film in accordance with an embodiment of the invention;

FIG. 3 is an illustration of a technique of thin film deposition in accordance with an embodiment of the invention;

FIG. 4 is an illustration of a thin film deposited by prior art techniques;

FIG. 5 is an illustration of a thin film deposited in accordance with an embodiment of the invention; and

FIG. 6 is an illustration relating to an example of a thin film produced in accordance with an embodiment of the invention.

### DETAILED DESCRIPTION

The invention relates to thin films that are at least binary in nature and their deposition by evaporative techniques. In the semiconductor industry it is often important to maintain both the stoichiometry in thin films and as well as the uniformity of the films. Thermal evaporation is an inexpensive and commonly used method of forming such films. This invention utilizes a method of increasing the surface area of an evaporation container, preferably by using an inert medium added to source materials held by the container that are to form the binary (or greater) film. By this method, films of increased uniformity and maintained stoichiometry are achievable.

In the following detailed description, reference is made to various specific embodiments in which the invention may be practiced. These embodiments are described with sufficient detail to enable those skilled in the art to practice the invention, and it is to be understood that other embodiments may be employed, and that structural and electrical changes may be made without departing from the spirit or scope of the present invention.

The terms “substrate” and “wafer” can be used interchangeably in the following description and may include any foundation surface, but preferably a semiconductor-based structure. The structure should be understood to include silicon, siicon-on insulator (SOI), silicon-on-sapphire (SOS), doped and undoped semiconductors, epitaxial layers of silicon supported by a base semiconductor foundation, and other semiconductor structures. The semiconductor need not be silicon-based. The semiconductor could be silicon-germanium, germanium, or gallium arsenide. When reference is made to the substrate in the following description, previous process steps may have been utilized to form regions or junctions in or over the base semiconductor or foundation.

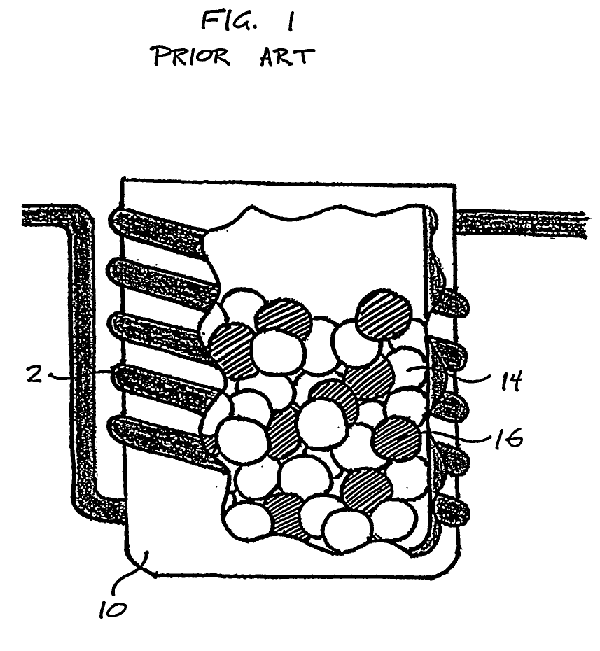

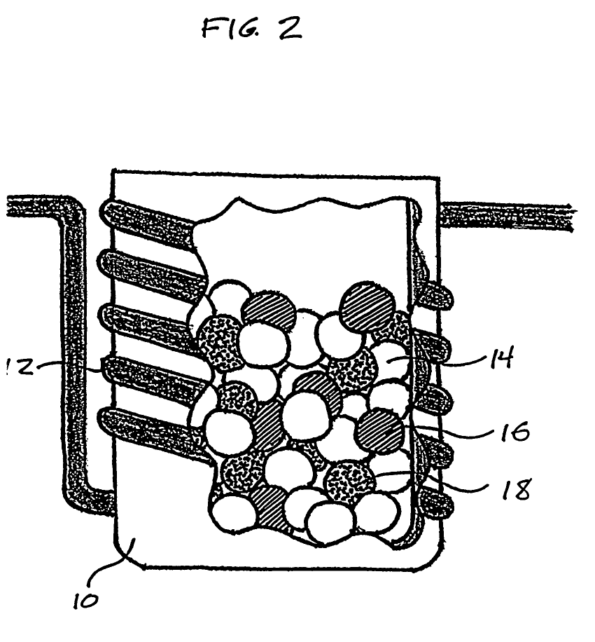

Now referring to the figures, where like reference numbers denote like features, FIG. 1 shows an example of how evaporative deposition techniques in the prior art utilized source material. Prior art binary films were produced by thermal evaporation by applying thermal energy to source materials until they vaporized and then condensed on the desired target (e.g., a semiconductor wafer). As is shown, to form a binary film, source materials comprising a first source material 14 and a second source material 16 are added to an evaporation container 10, such as a crucible or boat. These two source materials 14 and 16, generally in the form of solid pellets shaped like marbles or pebbles, are the two components that are desired to physically or chemically combine to form the binary film. The source materials 14 and 16 can be in the form of two sets of pellets, each respective set comprising one of the first or second source materials 14 and 16 as shown in FIGS. 1 and 2. Alternatively, the two source materials can be preliminarily combined in a desired stoichiometry to form one set of pellets. As another alternative, the source materials 14 and 16 can be in the form of a single solid entity comprising the entire mass of source material. In the prior art, the two source materials 14 and 16, once added to the evaporation container 10, were subjected to thermal energy from a heat source 12, typically a resistive heating coil, laser, or electron beam. Upon application of enough thermal energy, the materials 12 and 16 melt and then vaporize to form the thin film upon condensing. However, because the source materials 14 and 16 often have very divergent physical characteristics (e.g., melting and boiling points), one of the materials 14 typically melts and vaporizes, and subsequently condenses on the target before the other of the source materials 16, leading to undesirable film stoichiometric distribution and uniformity. These divergent physical characteristics can also lead to dissociation (the separation of chemical components into simpler fragments) during evaporation, also negatively impacting film quality.

In accordance with the invention, the problems associated with the prior art techniques can be mitigated, as shown in FIG. 2, by the addition of an inert medium 18 to the source materials 14 and 16 (be them in any of the alternative forms) prior to the addition of thermal energy. The inert medium 18 is preferably a material that has a high melting temperature (above that of either source material 14 and 16), and is non-reactive in general, and particularly with the source materials 14 and 16. The inert medium 18, for instance, can be a silicon or a ceramic based material.

Typically the inert medium 18 consists of solid material similar in shape and size to the source materials 14 and 16 (e.g., pellets); however, it will be readily apparent to those of skill in the art that a multitude of variations in size and shape of the inert medium 18 are possible and, depending on the circumstances, desirable. Though the shape of the inert medium 18 can vary, generally spherical shapes are preferred because such a design achieves the maximum relative surface area without interfering with the evaporation process (because of folds, sharp corners, etc.). Further, the added inert medium 18 are preferably large enough to effectively maximize evaporation container 10 surface area by contacting the container 10 itself, as well as the source materials 14 and 16. However, the size of the inert medium 18 should not be so large as to interfere with the evaporation process (e.g., by blocking the evaporation container 10 opening).

As shown in FIG. 2, the inert medium 18 is dispersed throughout the source material 14 and 16 within the evaporation container 10. Preferably, enough inert medium 18 is added to the source materials 14 and 16 so that the thermal energy used for evaporation can be efficiently transferred from the evaporation container 10 to the source materials 14 and 16 as equally as possible.

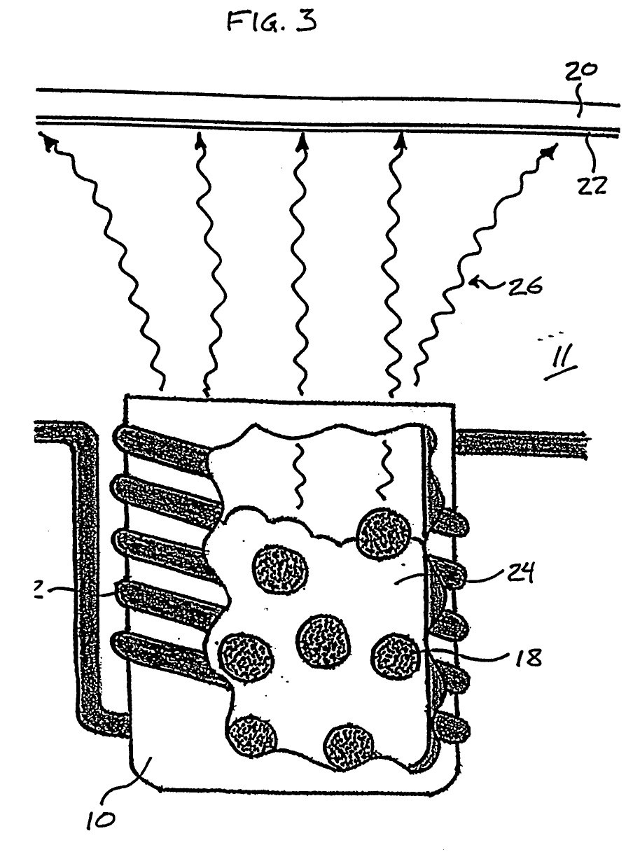

As shown in FIG. 3, The added inert medium 18 of the invention serves to increase the heating area during the evaporation process. The addition of the inert medium 18 also reduces the amount of power needed to melt the source material 14 and 16, even towards the middle of the evaporation container 10, which typically in the prior art required additional energy. When heat is applied by the heat source 12, preferably in a vacuum chamber 11, the source material 14 and 16 in the evaporation container melts to form a liquefied source material 24, which upon continued application of thermal energy becomes a vaporized source material 26. This vaporized source material 26 condenses upon contacting the cooler wafer 20, which is positioned in proximity to the evaporation container (preferably within a vacuum evaporation chamber 11, positioned above and facing the source material). Upon condensing, the vaporized source material 26 forms a thin film 22 comprising a combination of source materials 14 and 16, desirably in the same stoichiometric ratio as initially present in the evaporation container. Typically, a film of about 25 Å to about 5 μm is desired as useful in the semiconductor industry, which can be produced using the invention.

The uneven heating, melting, and evaporation of the source materials 14 and 16 found in the prior art is diminished so that the two source materials 14 and 16 melt and vaporize more quickly and more synchronously. The result is that the resultant film deposits in less time, leading to more uniform films, and has a more desirable stoichiometry due, in part, to less dissociation.

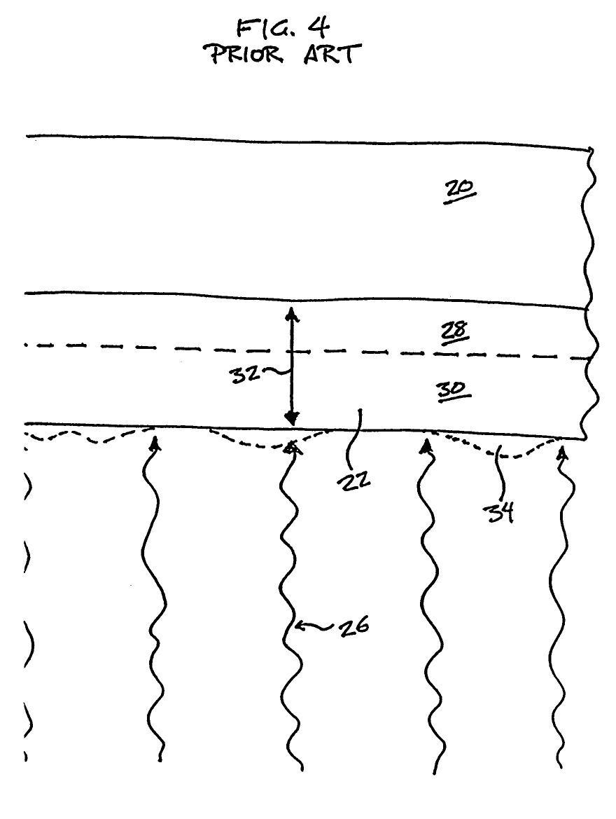

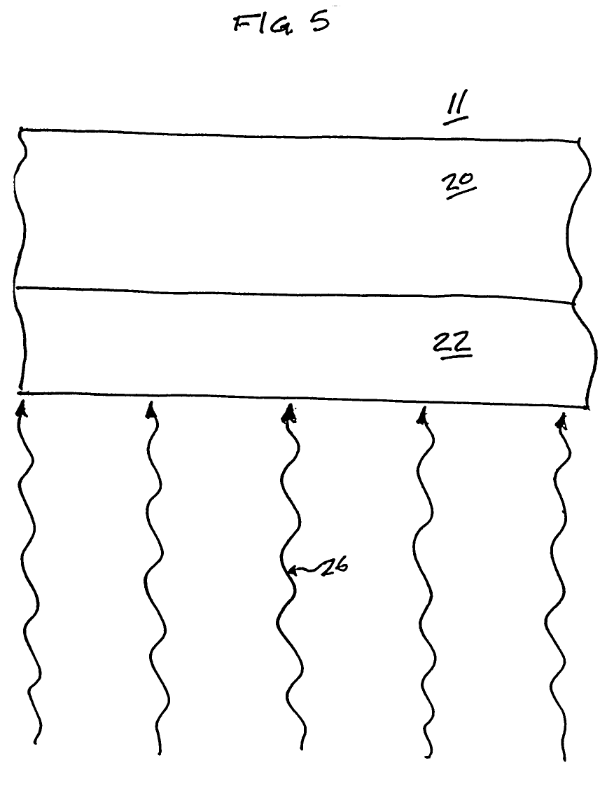

As illustrated in FIG. 4, because of the uneven heating, melting, evaporation, and dissociation of components found in the prior art, the first portion 28 of the thin film 22 was, in general, predominantly comprised of whichever of the source materials 14 and 16 has the lowest melting and boiling points, wherein the second portion 30 of the thin film 22 has closer to the desired stoichiometry, being deposited once the second of the source materials 14 and 16 reaches its boiling point. It is also possible that under the circumstances of the prior art that the outermost portion of the thin film 22 would have an undesirably high amount of the second source material 14 or 16 to vaporize, which would continue to be deposited even after the first source material is exhausted. Thus, a gradient 32 would be created in the thin film 22 where the proportional amounts of source material 14 and 16 shifts from one extreme to the other through the thickness of the film 22. Additionally, under such circumstances, an uneven surface 34 could develop on the thin film 22. As shown in FIG. 5, when compared to the thin film 22 of the prior art, the invention can achieve a thinner, more uniform thin film 22 of a more consistent desired stoichiometry.

Though this invention has been described primarily with reference to binary films utilizing two source materials 14 and 16, it can also achieve thin films 22 of desired uniformity and stoichiometry utilizing three or more source materials.

### EXAMPLE

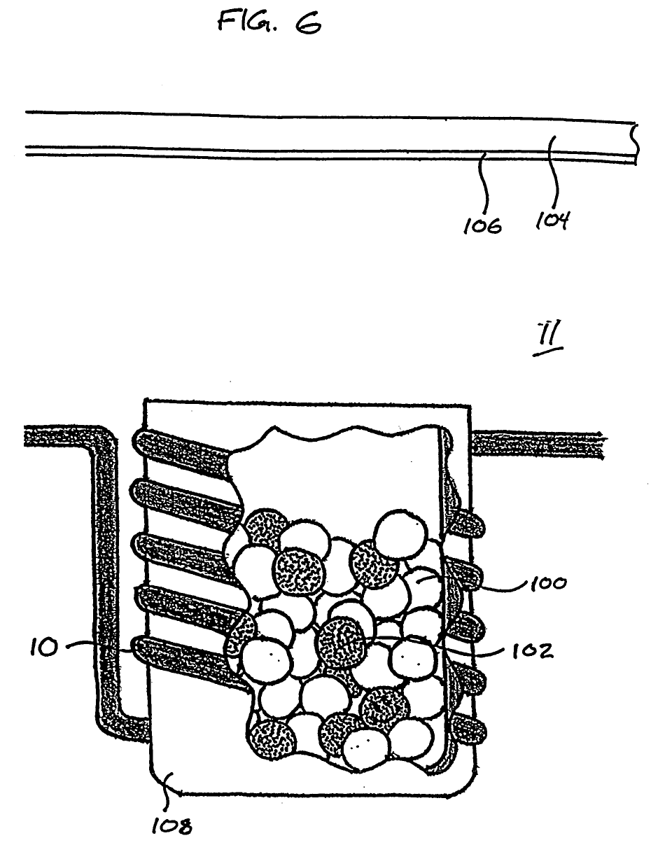

The following supporting data was obtained in experiments using actual embodiments of the invention. Table I below shows experimental results. The experiments are explained in reference to FIG. 6.

TABLE I

| | | | | Film | Film |
|---|---|---|---|---|---|
| | Inert | Source | Power | Silver | Selenium |
| | Medium | Material | (% maximum) | (mole %) | (mole %) |
| Control | None added | Ag₂Se | 11% | 59.60 | 40.4 |
| Run 1 | Si added | Ag₂Se | 13% | 64.80 | 35.2 |
| Run 2 | Si added | Ag₂Se | 16% | 68.90 | 31.1 |

Each experimental run was conducted in a vacuum chamber 11 and used a standard ceramic crucible 108 as an evaporation container 10 and standard resistive heating coils 110 for a heat source 12, as is known in the art. As a deposition target, a 3500 Å layer of TEOS oxide over a 200 mm silicon (Si) wafer having a (111) crystalline orientation served as a substrate 104 upon which to condense the thin film. The source material used in all runs were pellets 100 formed of silver and selenium (Ag₂Se), manufactured on site to be of known stoichiometry. The target stoichiometry for the deposited thin films was Ag₆₆Se₃₃ and the initial stoichiometry of the source material reflected this desired film stoichiometry in a 2:1 ratio (with Ag being no greater than 2). For each run, thermal energy was applied to the crucible 108 and its contents by the resistive heating coils 110 as a function of the % total power. The Ag₂Se source pellets 100 were heated for a minimum of 60 seconds to vaporize. Time to boiling was subjective and a function of the % power used. The desired thickness for each deposited experimental film was 500 Å.

For the Control Run (reflecting prior art techniques), no inert medium was added to the Ag₂Se source pellets 100. The power used was about 11% of total power. As is shown in Table I, the resulting stoichiometry of the deposited film did not achieve the target 2:1 Ag to Se ratio, but the resulting 3:2 ratio did reflect results common to techniques used in the prior art. The undesired stoichiometry was due to the dissimilar physical characteristics of the silver and selenium, uneven heating, and dissociation, resulting in uneven deposition rates and amounts between the source materials.

As shown in Table 1, Run 1 utilized the same Ag₂Se source pellets 100, but inert silicon (Si) media 102 was added in accordance with the invention. Thermal energy was applied by the resistive heating coils at about 13% total power. The 500 Å film was deposited and determined by subsequent analysis to have close to target stoichiometry. Run 2 also utilized inert silicon (Si) media 102 in accordance with the invention. For Run 2, thermal energy was applied at about 16% total power. The resulting film was not as close to the target stoichiometry as with Run 1, but was still closer than the Control Run, which used no inert media.

The above description, examples, and accompanying drawings are only illustrative of exemplary embodiments, which can achieve the features and advantages of the present invention. It is not intended that the invention be limited to the embodiments shown and described in detail herein. The invention can be modified to incorporate any number of variations, alterations, substitutions or equivalent arrangements not heretofore described, but which are commensurate with the spirit and scope of the invention. Accordingly, the invention is not to be considered as being limited by the foregoing description, but is only limited by the scope of the appended claims.

1-40. (canceled)

41. An apparatus for physical deposition of a film by thermal evaporation, comprising:
a container suitable to withstand temperatures in excess of a first temperature;
at least two source materials within said container, each of said at least two source materials having a respective different boiling point;
an inert medium within said container and interspersed among said at least two source materials, said inert medium having a boiling point in excess of said respective boiling points of said at least two source materials; and
a thermal energy generator capable of raising the temperature of said container, said at least two source materials, and said inert medium to above said respective boiling points of said at least two source materials, but below the boiling point of said inert medium.

42. The method of claim 41, wherein said inert medium is at least one member selected from the group consisting of: a silicon-based material and a ceramic-based material.

43. The apparatus of claim 42, wherein said inert medium comprises a silicon-based material.

44. The apparatus of claim 42, wherein said inert medium comprises a ceramic-based material.

45. The apparatus of claim 41, wherein said thermal energy generator comprises a resistive heating coil.

46. The apparatus of claim 41, wherein said at least two source materials comprise silver and selenium.

47. The apparatus of claim 46, wherein said silver and selenium are in the form of Ag₂Se.

48. The apparatus if claim 41, further comprising a vacuum chamber.

49. An apparatus for depositing a multi-component film, comprising:
a container;
a first material within said container, said first material having a first boiling point;
a second material within said container, said second material having a second boiling point different from said first boiling point;
an inert medium within said container and interspersed with said first and second materials, said inert medium being non-reactive with said first and second materials and having a third boiling point greater than said first and second boiling points; and
a heat source configured to vaporize said first material and said second material in said container.

50. The apparatus of claim 49, further comprising a third material within said container, said third material having a third boiling point different from at least one of said first and second boiling points.

51. The apparatus of claim 49, wherein said first material is a metal and said second material is a chalcogen.

52. The apparatus of claim 49, wherein said first material is silver.

53. The apparatus of claim 49, wherein said second material is selenium.

54. The apparatus of claim 49, wherein said first material is present in said container in the form of first material pellets and said second material is present in said container in the form of second material pellets.

55. The apparatus of claim 54, wherein said first material pellets and said second material pellets are generally spherical.

56. The apparatus of claim 49, wherein said heat source is an electric coil.

57. The apparatus of claim 49, wherein said inert medium comprises ceramic.

58. The apparatus of claim 49, wherein said inert medium comprises silicon.
